(19) United States
(12) Patent Application Publication
(10) Pub. No.: US 2024/0289526 A1
(43) Pub. Date: Aug. 29, 2024

(54) SIMULATOR AND METHOD FOR OPERATING A SIMULATOR

(71) Applicant: dSPACE GmbH, Paderborn (DE)

(72) Inventors: Axel KIFFE, Paderborn (DE); Thorben HOFFSTADT, Paderborn (DE)

(21) Appl. No.: 18/573,457

(22) PCT Filed: Jul. 1, 2022
(86) PCT No.: PCT/EP2022/068231

§ 371 Date: Feb. 13, 2024

(30) Foreign Application Priority Data
Jul. 2, 2021 (DE) 10 2021 117 143.1

(51) Int. Cl. G06F 30/3308

(52) U.S. Cl. CPC G06F 30/3308

(57) ABSTRACT

A simulator is configured for simulating a power electronics circuit having at least one switch for a test bench having at least one computer. The simulator includes a state identification apparatus configured for identifying a state of the at least one switch, wherein the state is based on a forced or a natural switching operation, each of which has at least two state conditions for at least one first electrical parameter of the at least one electrical switch. The simulator is configured for outputting at least one output value of the power electronics circuit on the basis of the state.

### CROSS-REFERENCE TO PRIOR APPLICATIONS

This application is a U.S. National Phase application under 35 U.S.C. § 371 of International Application No. PCT/EP2022/068231, filed on Jul. 1, 2022, and claims benefit to German Patent Application No. DE 10 2021 117 143.1, filed on Jul. 2, 2021. The International Application was published in German on Jan. 5, 2023 as WO 2023/275347 A1 under PCT Article 21(2).

### TECHNICAL FIELD

The application relates to a simulator for simulating a power electronics circuit, and to a method for operating a simulator.

### SUMMARY

In an exemplary embodiment, the present invention provides a simulator configured for simulating a power electronics circuit having at least one switch for a test bench having at least one computer. The simulator includes a state identification apparatus configured for identifying a state of the at least one switch, wherein the state is based on a forced or a natural switching operation, each of which has at least two state conditions for at least one first electrical parameter of the at least one electrical switch. The simulator is configured for outputting at least one output value of the power electronics circuit on the basis of the state.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows a combination of the simulator and the device under test (DUT);

FIG. 2 is a first block diagram of the state identification;

FIG. 3 is a second block diagram of the state identification;

FIG. 4 is a third block diagram of the state identification;

FIG. 5 is a fourth block diagram of the state identification;

FIG. 6 shows a hardware structure of the simulator;

FIG. 7 is a state diagram; and

FIG. 8 is a table for the state conditions according to which the state of the at least one switch is identified.

In the drawings, the same reference signs are used for the same or similar elements.

### DETAILED DESCRIPTION

Exemplary embodiments of the invention provide a simulator and a method for operating a simulator that reliably identifies the state of simulated switches for power electronics circuits.

The simulator and the method for operating the simulator identify a state of the switch by way of two state conditions in each case for a natural or a forced switching operation. As a result, it is possible to reliably draw conclusions on the state of the switch.

Accordingly, a simulator is provided that simulates a power electronics circuit having at least one switch for, e.g., a test bench having at least one computer, comprising a state identification apparatus that identifies a state of the at least one switch, wherein the state is based on a forced or a natural switching operation, each of which has at least two state conditions for at least one first electrical parameter of the at least one electrical switch. The simulator outputs at least one output value of the power electronics circuit on the basis of said state. The same applies to the method for operating the simulator.

The simulator is a device that comprises a computer. A power electronics circuit having at least one switch is simulated by the computer. By way of example, the simulator is connected to what is referred to as a device under test (DUT) so that, using said device (simulator), the proper functioning of the device under test is tested. In this case, the simulator simulates the power electronics circuit to which the device under test is actually connected during use. Usually, the device under test is a controller on which various software functions run, which use output values of the power electronics circuit and/or control and/or monitor the power electronics circuit.

In such a test bench for the DUT, which is also referred to as a hardware-in-the-loop (HIL) test bench, the DUT is intended to be tested in various situations to check whether it still functions properly in those situations. Parameterization is also possible here. The simulator and the DUT are usually electrically connected via lines. However, it is also possible for wireless transmission between the simulator and the DUT to be provided. Mixtures of wired and wireless transmission are also possible.

The computer of the simulator can be one or more processors or, for example, what is known as an FPGA (field-programmable gate array), on which the various computing functions which the FPGA is intended to execute are then programmed. In this case, the computer can be formed of various hardware resources for executing the computing functions.

Power electronics circuits are increasingly being used in a huge range of technologies. A power electronics circuit is intended for transforming electrical energy, for example. The actuation of actuators such as an electric motor may also be one of the tasks of a power electronics circuit. In addition, diagnostic functions for diagnosing actuators or an energy source such as a battery are possible. In particular, an energy source, for example a battery, can be charged by a power electronics circuit of this kind. As a result, a DUT that cooperates with a battery can then be tested, for example.

A power electronics circuit is usually connected to batteries or an electrical mains supply and converts the electrical energy obtained therefrom in accordance with the requirements stipulated for it. For this purpose, the power electronics circuit can comprise rectifiers and/or inverters. A key component of such power electronics circuits having, for example, rectifiers and/or inverters are the circuit breakers, in particular semiconductor switches, which are referred to in the present case as switches. These circuit breakers are usually transistors, diodes, or thyristors that are able to switch the required currents that may occur.

In a simulation, unlike in a real-world design, ideal switches can be defined, the state of which is identified in accordance with this application.

For this purpose, a state identification apparatus is provided, which is formed, for example, on the FPGA. In this case, the state identification apparatus uses at least two conditions for each electrical parameter; in doing so, the state identification apparatus distinguishes between what is referred to as a forced switching operation and a natural switching operation. In other words, there are at least two conditions for each forced and natural switching operation. This distinction is drawn by testing the at least four conditions for the electrical parameters. The electrical parameters are, for example, currents and voltages that can be measured at the switches.

A forced switching operation is one that is actively triggered by applying an electrical signal from outside the switch, e.g., at a switch input provided for this purpose. The electrical signal is provided for triggering the forced switching operation.

A natural switching operation is triggered by the behavior of at least one electrical variable within the switch, with the electrical variable reaching, falling below, or exceeding a threshold value, for example. The electrical variable that triggers the natural switching operation occurs naturally at the switch, for example a flowing current or an applied voltage.

On the basis of this identified state, an output value of the power electronics circuit is output, for example to the DUT. The simulator allows the switching state to be reliably identified from sampled discrete values.

The state condition can be understood to mean that ascertained electrical parameters are tested using predetermined conditions for those parameters. Depending on whether these conditions are met, the state, i.e., closed or open, is then determined. If, for example, the ascertainable current flowing through the switch is taken as the electrical parameter, this current can then be tested as to whether this current is above or below predetermined limits. If it is, a conclusion is drawn on the state of the switch.

By way of example, the output value can be an output vector having a plurality of components, which are then output via an interface unit, for example. An input vector that indicates currents and/or voltages applied to the simulated power electronics circuit is then applied accordingly to the simulator and thus to the simulated power electronics circuit. The same applies to the method.

In one embodiment example, the state identification apparatus comprises the respective state conditions for an ideal switch, for a diode, for a thyristor, and/or for a MOSFET, i.e., for a field-effect transistor. The state identification apparatus is thus configured for respectively identifying each state. Said stated switches are those that are usually used in a power electronics circuit. However, it is also possible, for example, to define further transistor types by way of such state conditions. Additionally or alternatively, these transistor types can be defined for the simulator.

In addition, it is provided that the state identification apparatus is configured for taking account of the at least one first electrical parameter from a previous simulation step when identifying the state of the at least one switch. In such switches, the history may also be relevant in order to draw conclusions on the current state of the particular switch.

In one embodiment, a Dirac impulse identification apparatus is provided, which is configured to identify a Dirac impulse via a Boolean function on the basis of a first output signal of the state identification apparatus, and to output a Dirac signal on that basis. Dirac impulses, which do not normally occur in real-world switches, can occur in ideal switches.

Therefore, in a simulation of this kind, it is necessary to identify and then accordingly process such Dirac impulses. The Dirac signal flags the occurrence of a Dirac impulse which may be associated with a switching operation of the switch. Dirac impulses occur after forced switching operations. They can be identified owing to the above-described distinction between natural and forced switching operations. Thus, the behavior of the simulation can be adapted such that proper account is taken of the so-called induced switching events caused by the Dirac impulse.

In addition, it is provided to set the state of the at least one switch to a predetermined value on the basis of the Dirac signal. The predetermined value is intended to emulate the behavior of the real-world switch and replace the Dirac impulse of the ideal switch. This is one example of how the occurrence of such a Dirac impulse can be processed in the simulation.

In one embodiment, a toggle detector is provided, which outputs a toggle signal on the basis of a sign analysis of at least one second electrical parameter for the at least one switch, wherein the toggle signal influences the identification of the state. Thus, toggling or swinging between two switching states can be identified and prevented. The sign analysis is advantageous since it makes it possible to identify when a signal is jumping back and forth between different polarities, for example.

In addition, it is provided that the state identification apparatus takes account of the identification of the state from a previous simulation step. Thus, conclusions can be reliably drawn on the state of the switch.

In one embodiment, it is provided that the state identification apparatus is split into an impulse part for generating a second output signal and a non-impulse part for generating a third output signal. In this case, a fusion module is provided, which generates a fourth output signal on the basis of the second and the third output signal. This splitting makes it possible to carry out a very precise state identification on each switch.

In one embodiment, it is provided that the fusion module is configured for generating the fourth output signal on the basis of the Dirac signal.

The computer of the simulator can comprise at least one FPGA. Thus, one or more FPGAs can be used in combination with one another or also with many different kinds of processors.

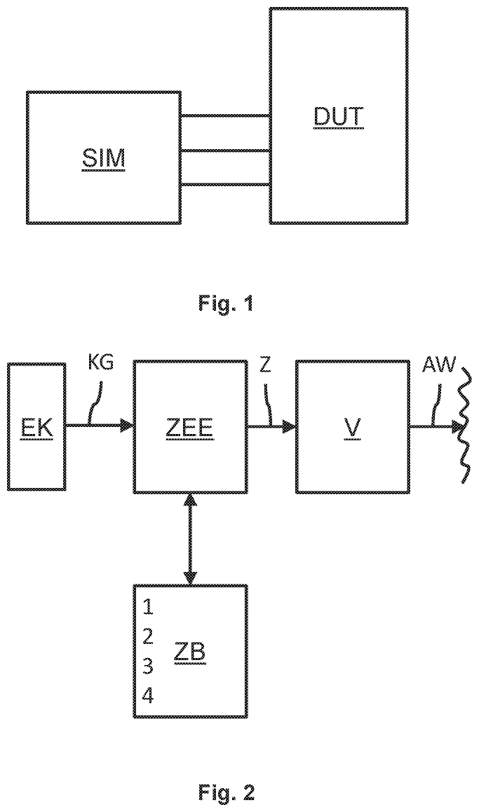

FIG. 1 shows an interconnection of the simulator SIM and a device to be tested, which is referred to as the DUT, via three lines. The number of lines is merely an example and could be different. Wireless transmission of signals between the simulator SIM and the device DUT is also possible. Such constructions are also referred to as test benches and are widely used in both the automotive industry and other sectors. The simulator SIM simulates a power circuit, which is operatively connected to the device DUT. By way of example, the device DUT is a controller that controls and/or monitors the power electronics. In the present case, control includes both open-loop and closed-loop control. A test bench of this kind can then be used to comprehensively test the software and hardware of the device. By way of example, the power electronics circuit can simulate a charger for a battery, the DUT being the controller of the charger.

In a block diagram, FIG. 2 shows an input unit EK, which outputs a first electrical parameter KG to a state identification apparatus ZEE. The state identification apparatus ZEE tests the first electrical parameter KG against state conditions ZB to establish the state of the switch that emits the first electrical parameter KG or at which the first electrical parameter KG is ascertained. In this case, the state conditions are intended for both natural and forced switching operations, and so usually four conditions can be tested, i.e., two each for the forced and the natural switching operation. The state itself, as determined by the state identification apparatus ZEE, is then relayed to the output unit V. The first electrical parameter KG can be the values from a current clock cycle and from a previous clock cycle. The output unit V then emits an output value AW to the outside world via an input/output unit IO to the DUT.

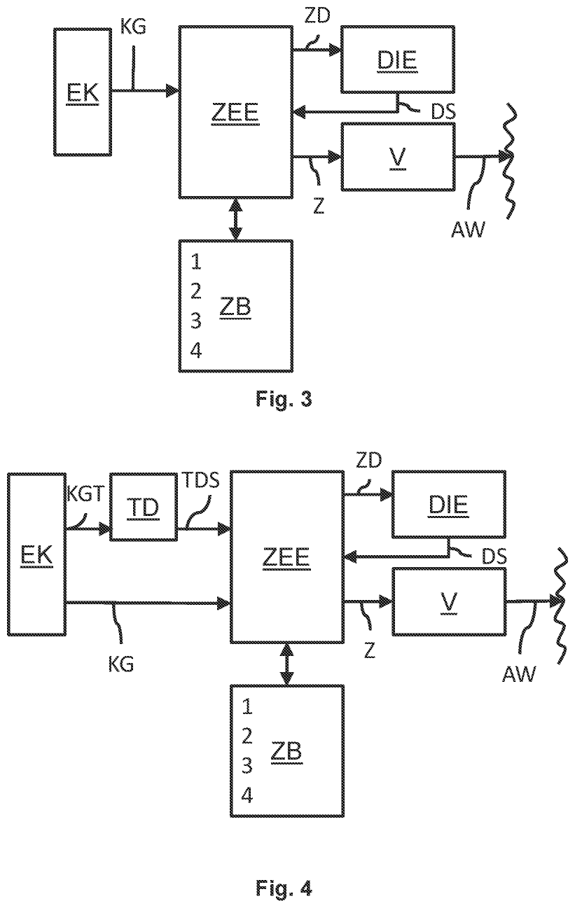

FIG. 3 illustrates the state identification apparatus with further refinement in a further block diagram. The input unit EK delivers the first electrical parameter KG to the state identification apparatus ZEE. In turn, the state identification apparatus ZEE uses the state conditions ZB to determine the state of the switch that has emitted the electrical parameters KG. The state identification apparatus ZEE delivers a value ZD to an impulse identification apparatus DIE, which emits a Dirac signal DS to the state identification apparatus ZEE on the basis of said value. The state identification apparatus ZEE now also assesses the Dirac signal DS to determine the state Z and output it to the output unit V. The output unit V then outputs the output value AW on the basis of the state Z.

FIG. 4 provides a further refinement of the state identification apparatus ZEE. In this case, a toggle state of the switch is now additionally identified by a toggle detector. The input unit EK now outputs the first electrical parameter KG and a second electrical parameter KGT. The second electrical parameter KGT is output to the toggle detector TD. On the basis of the analysis of the second electrical parameters KGT, the toggle detector TD identifies whether or not a toggle state is present. For this purpose, the toggle detector TD uses, for example, a sign analysis to identify whether the second electrical parameter KGT is swinging back and forth between the polarities, for example. On that basis, a signal, namely a toggle signal TDS, is output to the state identification apparatus ZEE. The input unit EK likewise delivers the first electrical parameter KG to the state identification apparatus ZEE. Furthermore, the state identification apparatus ZEE is also connected to the Dirac impulse identification apparatus DIE and exchanges the above-described signals ZB and DS therewith. Using these signals and the state conditions ZB, the state identification apparatus ZEE ascertains the state Z, which is output to the output unit V, which then generates the output value AW on that basis.

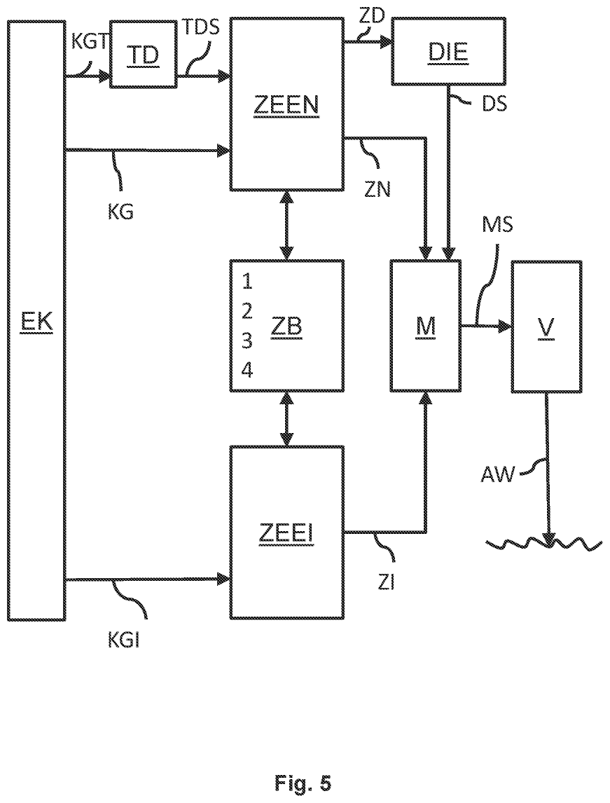

FIG. 5 refines the state identification further. The input unit EK delivers the first electrical parameter KG to a non-impulse part ZEEN of the state identification apparatus. A second electrical parameter KGT is delivered by the input unit EK to the toggle detector TD, which delivers the toggle signal TDS to the non-impulse part ZEEN on the basis of the sign analysis. The non-impulse part ZEEN is connected to the Dirac impulse identification apparatus DIE and emits the signal ZD thereto as described above. The Dirac impulse identification apparatus DIE outputs the Dirac signal DS to a fusion module M on the basis of the signal ZD. The non-impulse part ZEEN emits the state signal ZN to the fusion module M. The non-impulse part ZEEN again uses the state conditions ZB when identifying the state.

The input unit EK delivers a third electrical parameter KGI to an impulse part ZEEI. On the basis of this third electrical parameter KGI, the impulse part ZEEI determines an output signal ZI using the state conditions ZB. This second output signal ZI is likewise given to the fusion module M. From its input signals, the fusion module M determines an output signal MS, which is emitted to the output unit V, which generates the output value AW therefrom. The fusion module M uses logical functions for combining the input signals. The state signal ZI can overrule the results of the other modules.

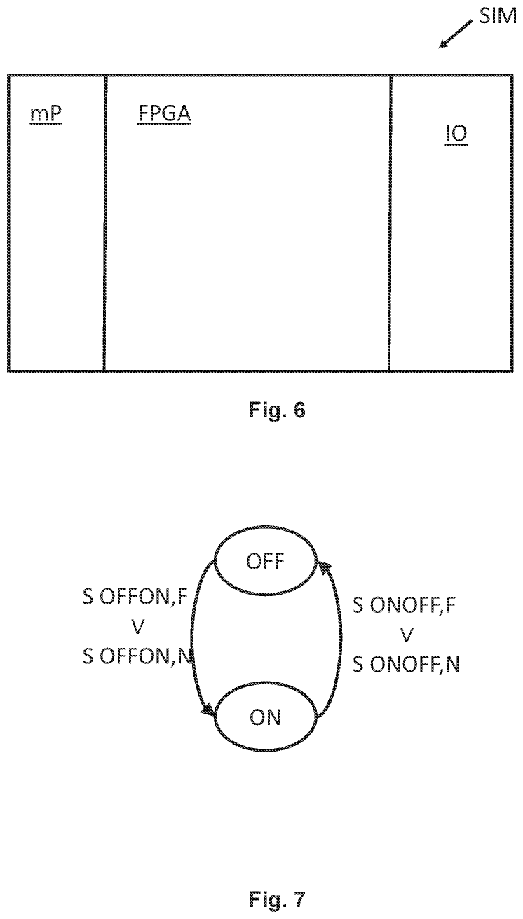

FIG. 6 schematically shows the hardware structure of the computer of the simulator SIM. In the present case, a microprocessor mP can be used. Furthermore, an FPGA is provided, in which the state identification apparatuses are formed. Moreover, an input/output interface IO for receiving the input vector, for example, and outputting the output value AW is provided. The input/output interface IO has registers, for example.

The state diagram in FIG. 7 shows the conditions on the basis of which the state changes between the closed and the open switch and vice versa are identified in the state identification apparatus ZEE. In this case, for the state change from “OFF,” or open, to “ON,” or closed, the state condition for the forced switching operation S OFFON,F is mathematically OR-gated with the natural switching operation S OFFON,N. For the state change from “ON,” or closed, to “OFF,” or open, the state condition for the forced switching operation S ONOFF,F is mathematically OR-gated with the natural switching operation S ONOFF,N. Therefore, the state changes when a natural and/or a forced switching event occurs.

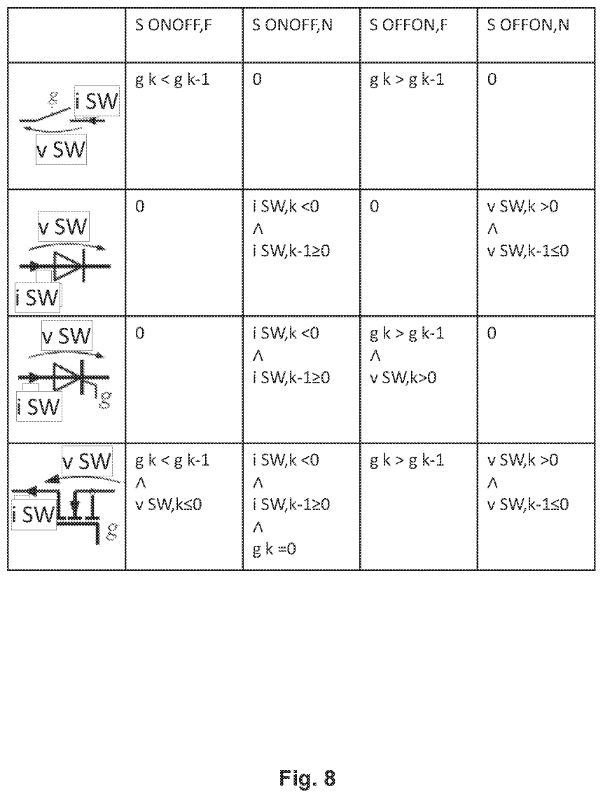

These changes are determined by the conditions set out in a table in FIG. 8. This table has four rows, namely the first for the ideal switch, the second for the diode, the third for the thyristor, and the fourth for the MOSFET.

The column S ONOFF,F describes the change of a forced switching operation from on to off, i.e., from closed to open. The column S ONOFF,N is for the same operation from closed to open but for a natural switching operation. The column S OFFON,F describes the change of a forced switching operation from off to on, i.e. from open to closed. The column S OFFON,N is for the same operation from open to closed but for a natural switching operation.

The switching operations are identified on the basis of the signals g, i SW and v SW. g k, i SW,k and v SW,k each denote the signals of the current clock cycle. g k−1, i SW,k−1 and v SW,k−1 each denote the signals of the previous clock cycle. The signal g k is a so-called gate signal of the various switches. i SW is a current flowing through the switch. v SW is a voltage applied to the switch.

0 as an entry in the table means that no such switching operations are occurring and/or identified for that particular switch type.

For the example of the switch in row 1 in the table from FIG. 8, this therefore means that no natural switching operations are occurring for this type of switch, since 0 is entered in the row for this switch in the column S ONOFF,N and S OFFON,N. This corresponds to the behavior of an ideal switch.

For the example of the switch in row 2 in the table from FIG. 8, this means that no forced switching operations are occurring for this type of switch, since 0 is entered in the row for this switch in the column S ONOFF,F and S OFFON,F. This corresponds to the behavior of a diode.

For the example of the switch in row 3 in the table from FIG. 8, this means that no forced switching operation is occurring for this type of switch from on to off, since 0 is entered in the corresponding column S ONOFF,F. In addition, no natural switching operation is identified for this type of switch from off to on, since 0 is entered in the corresponding column S OFFON,N. This corresponds to the behavior of a thyristor.

For the switch in the first row, the ideal switch, in the column S ONOFF,F the switching state is tested on the basis of the signal g, namely as to whether the value for the current testing operation is greater than that for the previous operation. The value 0 is entered in the column S ONOFF,N, i.e., no such switching operation is occurring.

In the second row, the conditions for the diode are tested, in this case on the basis of the diode current or the voltage across the diode; in the present case, 0 is provided for each forced switching operation, i.e., no such switching operations are occurring.

In the third row, the thyristor is indicated with the corresponding conditions. The fourth and final row indicates the corresponding conditions for the MOSFET.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE SIGNS

SIM Simulator
DUT Device under test
EK Input unit
V Output unit
ZEE State identification apparatus
Z State
ZB State condition
KG First electrical parameter
KGT Second electrical parameter
KGI Third electrical parameter
AW Output value
DIE Impulse identification apparatus
DS Dirac signal
TD Toggle detector
TDS Toggle signal
ZEEI Impulse part
ZD First output signal
ZI Second output signal
ZEEN Non-impulse part
ZN Third output signal
MS Fourth output signal
M Fusion module
g k Gate signal
mP Microprocessor
FPGA Computer
IO Input/output interface

1: A simulator configured for simulating a power electronics circuit having at least one switch for a test bench having at least one computer, the simulator comprising:
a state identification apparatus configured for identifying a state of the at least one switch, wherein the state is based on a forced or a natural switching operation, each of which has at least two state conditions for at least one first electrical parameter of the at least one electrical switch;
wherein the simulator is configured for outputting at least one output value of the power electronics circuit on the basis of the state.

2: The simulator according to claim 1, wherein the state identification apparatus comprises the respective state conditions for an ideal switch, for a diode, for a thyristor, and/or for a MOSFET for respectively identifying each state.

3: The simulator according to claim 1, wherein the state identification apparatus is configured for taking account of the at least one first electrical parameter from a previous simulation step when identifying the state of the at least one switch.

4: The simulator according to claim 1, wherein a Dirac impulse identification apparatus is provided, which is configured for identifying a Dirac impulse via a Boolean function on the basis of a first output signal of the state identification apparatus, and for outputting a Dirac signal on that basis.

5: The simulator according to claim 4, wherein the simulator is further configured for setting the state of the at least one switch to a predetermined value on the basis of the Dirac signal.

6: The simulator according to claim 1, wherein a toggle detector is provided, which is configured for outputting a toggle signal on the basis of a sign analysis of at least one second electrical parameter for the at least one switch, wherein the toggle signal influences the identification of the state.

7: The simulator according to claim 1, wherein the state identification apparatus is configured for taking account of the identification of the state from a previous simulation step.

8: The simulator according to claim 1, wherein the state identification apparatus is divided into an impulse part for generating a second output signal and a non-impulse part for generating a third output signal, wherein a fusion module is provided, which is configured for generating a fourth output signal on the basis of the second and the third output signal.

9: The simulator according to claim 8, wherein the fusion module is configured for generating the fourth output signal on the basis of the Dirac signal.

10: The simulator according to claim 1, wherein the computer comprises at least one field-programmable gate array (FPGA).

11: A method for operating a simulator that simulates a power electronics circuit having at least one switch for a test bench having at least one computer, the method comprising:
identifying, by a state identification apparatus, state of the at least one switch, wherein the state is based on a forced or a natural switching operation, each of which has at least two state conditions for at least one first electrical parameter of the at least one switch; and
outputting, by the simulator, an output value of the power electronics circuit on the basis of the state.
